(19) United States
(12) Patent Application Publication
(10) Pub. No.: US 2016/0291094 A1
(43) Pub. Date: Oct. 6, 2016

(54) METHOD FOR ESTIMATING THE AGEING OF A CELL OF A STORAGE BATTERY

(71) Applicant: RENAULT S.A.S., Boulogne-Billancourt (FR)

(72) Inventors: Laurent GAGNEUR, Montigny-le-Bretonneux (FR); Ana-Lucia DRIEMEYER-FRANCO, Montigny-le-Bretonneux (FR); Christophe FORGEZ, Compiegne (FR)

(73) Assignee: RENAULT S.A.S., Boulogne-Billancourt (FR)

(21) Appl. No.: 15/022,360

(22) PCT Filed: Sep. 16, 2014
(86) PCT No.: PCT/FR2014/052306

§ 371 Date: Mar. 16, 2016

(30) Foreign Application Priority Data
Sep. 18, 2013 (FR) 1358978

(51) Int. Cl. G01R 31/36

(52) U.S. Cl. CPC G01R 31/3679; G01R 31/3658; G01R 31/3648

(57) ABSTRACT

A method for estimating the ageing of at least one cell of a storage battery includes acquiring a voltage across the terminals of the cell and an amperage passing through the cell, and calculating a maximum capacitance and a level of charge of the cell in accordance with the voltage and the amperage acquired. The calculation is made by resolving: a system of discretized equations corresponding to a modelling of the cell as an electric circuit includes, in series, an ideal voltage source, a resistor, a first resistor and capacitor pair connected in parallel, and at least one second resistor and capacitor pair connected in parallel; and a discretized equation for estimating the variation in the maximum capacitance of the cell.

### TECHNICAL FIELD OF THE INVENTION

The present invention relates generally to the management of charge and discharge cycles of a storage battery.

The invention relates more particularly to a method for estimating the ageing of at least one cell of a storage battery, said method comprising the following steps:

a) acquiring a voltage at the terminals of said cell and an amperage of the current passing through said cell, and
b) calculating a maximum capacity and a state of charge of said cell in accordance with the voltage and the amperage of the current acquired in step a).

The invention can be applied particularly advantageously in motor vehicles equipped with an electric motor powered by a storage battery referred to as a traction battery.

### TECHNOLOGICAL BACKGROUND

As is well known, the electrical power that can be provided by a storage battery decreases during the course of a discharge cycle. The maximum amount of energy that can be stored by the storage battery in turn decreases progressively over the course of the service life of said battery.

In order to best draw some of the electrical power available in the battery in order to power an electric motor of a motor vehicle, in order to be able to predict the remaining autonomy of the vehicle before the battery is recharged, and in order to forecast the

In order to best draw some of the electrical power available in the battery in order to power an electric motor of a motor vehicle, in order to be able to predict the remaining autonomy of the vehicle before the battery is recharged, and in order to forecast the moment at which it will be necessary to change the entire battery or part thereof, it is sought to determine two particular parameters of the battery, which are the state of charge thereof denoted SOC and the maximum capacity thereof denoted Q.

The state of charge of the battery, which is generally expressed as a percentage, indicates the level of charge of the battery between a minimum charge level, at which the battery can no longer be used, and a maximum charge level.

The maximum capacity of the battery, which is generally expressed in ampere-hours, makes it possible to know the length of time for which the battery can provide an electrical current of a given amperage. This capacity degrades over time, in particular in accordance with the past temperature of the battery and past charge and discharge cycles thereof.

Document FR2971854 discloses a method for estimating this state of charge and this maximum capacity using an extended Kalman filter, of which the only basic relationship is constituted by the following equation:

$$\frac{dSOC}{dt} = \frac{I}{Q} ,$$

where l is the current passing through the storage battery.

The main disadvantages of this estimation method are constituted firstly by its lack of precision and reliability, secondly by its non-detection of a defective cell within the storage battery, and thirdly by its error of interpretation with regard to reversible capacity variations wrongly considered as being caused by ageing.

### OBJECT OF THE INVENTION

In order to overcome the above-mentioned disadvantages of the prior art, the present invention proposes an estimation method as defined in the introduction, in which in step b) the calculation is performed by resolving:
a system of discretized equations corresponding to a modeling of said cell as an electric circuit comprising, in series, an ideal voltage source, a resistor, a first resistor and capacitor pair connected in parallel, and at least one second resistor and capacitor pair connected in parallel, and
a discretized equation for estimating the variation of the maximum capacity of said cell.

In accordance with the invention the cell is thus modeled by an electric circuit.

The ideal voltage source then models the electrochemical potential of the cell. The difference between potentials at the terminals of this ideal voltage source is then dependent on the state of charge of the cell.

The resistor models the voltage drop induced by the connection of the cell and the internal resistance of the cell.

In the first resistor and capacitor pair connected in parallel, the resistor models the charge transfer phenomenon and the capacitor represents the double-layer phenomenon at the electrode/electrolyte interfaces. The term “charge transfer phenomenon” refers to the current resulting from oxidation and reduction reactions at the electrodes within the cell. The term “double-layer phenomenon” refers to the phenomenon of separation of the charges taking place at the interface between the electrode and the electrolyte.

The other resistor and capacitor pairs connected in parallel model the phenomenon of lithium ion diffusion in the cell, that is to say the polarization caused by the movement of the ions in the electrolyte and within the electrodes.

Thus, the states of charge and maximum capacities are calculated reliably by means of an algorithm representative of the actual electrochemical state of a battery cell, which quickly converges toward values close to reality.

In addition, thanks to the invention, it is possible to estimate the maximum capacity of each cell of the storage battery. Consequently, a comparison of these different maximum capacities will make it possible to detect a defective cell within the storage battery.

Further advantageous and non-limiting features of the estimation method according to the invention are as follows:
said system of discretized equations is expressed in the following form:

$$\{ \begin{matrix}SOC ( k ) = SOC ( k - 1 ) + \frac{( 1 + Δ Q ) \cdot I ( k - 1 ) \cdot {T}_{e}}{{Q}_{n}} \\ {V}_{dl} ( k ) = ( 1 - \frac{{T}_{e}}{{R}_{ct} {C}_{dl}} ) \cdot {V}_{dl} ( k - 1 ) + \frac{I ( k - 1 ) \cdot {T}_{e}}{{C}_{dl}} \\ {V}_{i} ( k ) = ( 1 - \frac{{T}_{e}}{{R}_{i} {C}_{i}} ) \cdot {V}_{i} ( k - 1 ) + \frac{I ( k - 1 ) \cdot {T}_{e}}{{C}_{i}}\end{matrix} , \\ where \\ i = 1 … N \\ {V}_{Cell} ( k ) = {E}_{eq} ( SOC ( k ) ) + {R}_{Ω} \cdot I ( k ) + {V}_{dl} ( k ) + {\sum }_{i = 1}^{N} {V}_{i} ( k )$$

with Tₑ a considered sampling period, k an incremental index, SOC the state of charge of said cell, I the amperage of the current passing through said cell, ΔQ being a parameter relating to a nominal capacity in early life and the instantaneous maximum capacity of said cell, V_{cell} the voltage at the terminals of the electric circuit, V_{dl} the voltage at the terminals of the first resistor and capacitor pair, of which the values are denoted R_{ct} and C_{dl} respectively, and Vᵢ the voltage at the terminals of the second resistor and capacitor pair, of which the values are denoted Rᵢ and Cᵢ respectively;
said discretized equation for estimating the variation of the maximum capacity of said cell is expressed in accordance with a parameter relating to a nominal capacity in early life and to the instantaneous maximum capacity of said cell;
said discretized equation for estimating the variation of the maximum capacity of said cell is expressed in the form ΔQ(k)=ΔQ(k−1). k being an incremental index;
said discretized equation for estimating the variation of the maximum capacity of said cell is expressed in the form ΔQ(k)=g(SOC(k−1),ΔQ(k−1),I(k−1),T(k−1)), where k is an incremental index, g is a function representative of the ageing dynamic of the cell, SOC is the state of charge of said cell, I is the amperage of the current passing through said cell, and T is a temperature measured across said cell;
in step b) the calculation is made by resolving said equations with the aid of a state observer of which the state vector comprises the state of charge of said cell, a variable representative of the capacity loss of said cell, the voltage at the terminals of the first resistor and capacitor pair, and the voltage at the terminals of each second resistor and capacitor pair;
in step b) the calculation is made by resolving said equations with the aid of a state observer of which the input vector comprises the voltage at the terminals of the electric circuit;
an additional step c) is provided, in which an indicator of a loss of autonomy of said cell is calculated in accordance with the maximum capacity of said cell calculated in step b):
in step c) the value of said indicator is modified only if the estimation of the maximum capacity of said cell is considered as converged:
in step c) the value of said indicator is modified only if the measured temperature of said storage battery is within the characterization temperature range in the early life of said storage battery;
in step c) the value of said state of health indicator is modified only if the state of charge of said storage battery is within a characterization range in the early life of said storage battery;
in step c) the value of said state of health indicator is modified only if the voltage acquired in step a) is within a characterization voltage range in the early life of said storage battery; and
in step c) the value of said state of health indicator is modified only if the amperage acquired in step a) is within a characterization amperage range in the early life of said storage battery.

### DETAILED DESCRIPTION OF AN EXEMPLARY EMBODIMENT

The following description with regard to the accompanying drawings, which are given by way of non-limiting example, will explain the essence of the invention and how the invention can be carried out.

In the accompanying drawings:

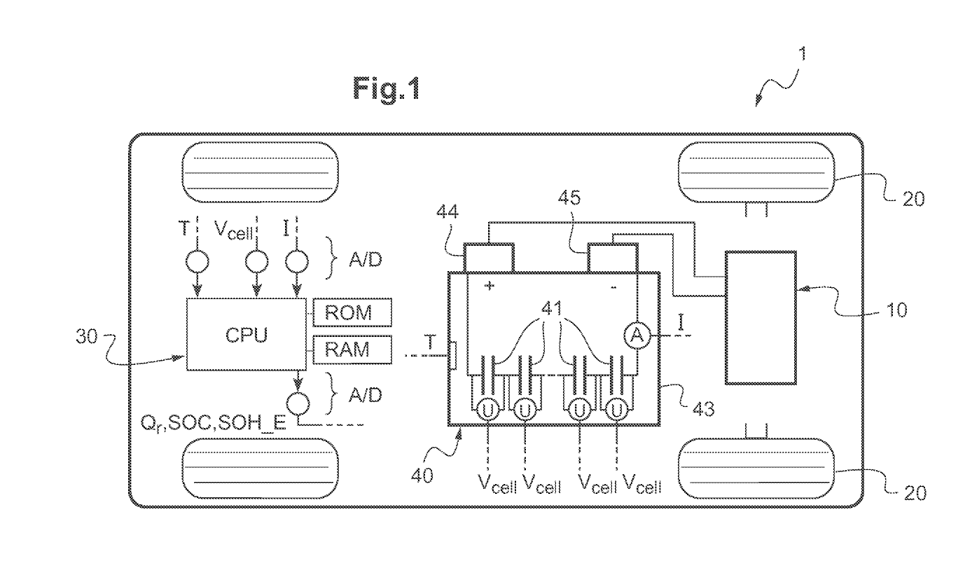

FIG. 1 is a schematic view of a motor vehicle equipped with a storage battery comprising a plurality of cells, and with a control unit suitable for implementing a method for estimating the ageing of these cells;

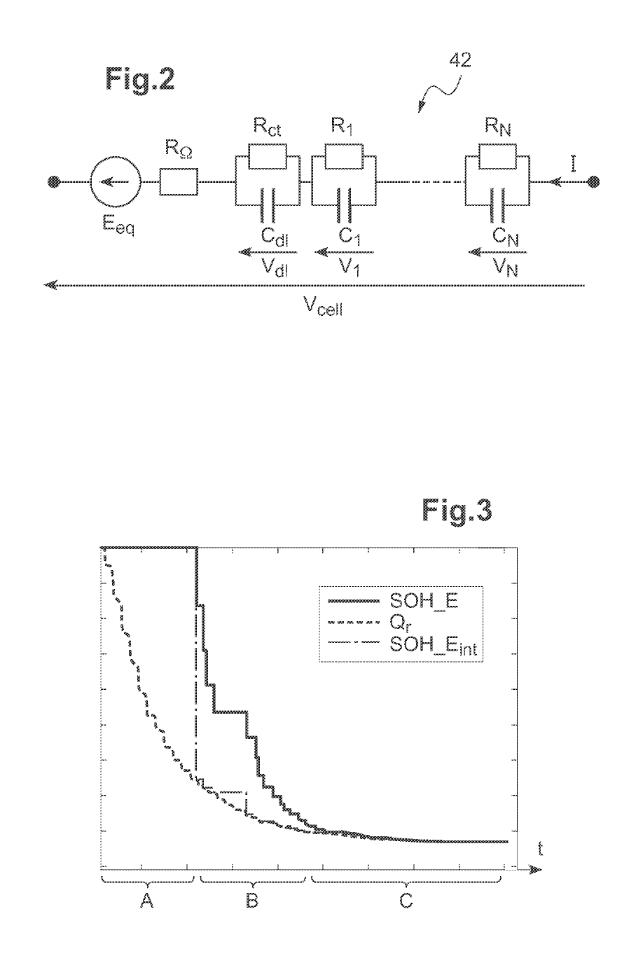

FIG. 2 is a circuit diagram modeling one of the cells of the storage battery from FIG. 1; and

FIG. 3 is a graph illustrating, with a dashed line, the variations of estimation of the maximum capacity of the cell from FIG. 2, with a dot-and-dash line, the variations of an intermediate state of health indicator, and, with a solid line, the variations of a filtered state of health indicator.

Firstly, in the following description, the term “storage battery” will be understood to mean an element able to store electrical energy when supplied with current by an external electric network, then able to release this electrical energy subsequently. A storage battery of this type for example may be of the electrochemical type (for example lithium-ion) or may be of a different type (for example capacitor).

FIG. 1 very schematically shows a motor vehicle 1.

This motor vehicle 1 is an electric vehicle here. It thus comprises an electric motor 10 provided in order to drive in rotation the driving wheels 20 of said vehicle.

In a variant the vehicle could be a hybrid vehicle, comprising an internal combustion engine and an electric motor for driving the driving wheels of said vehicle.

As shown in FIG. 1, the motor vehicle 1 comprises a storage battery, referred to as a traction battery 40.

This traction battery 40 is provided here exclusively in order to supply current to the electric motor 10. In a variant this traction battery could also be provided in order to supply current to different current-consuming electrical apparatuses, such as the power-steering system, the air-conditioning system, etc.

This traction battery 40 comprises an outer casing 43 from which two terminals emerge: one positive 44 and the other negative 45, said terminals being connected to the electric motor 10 via a power electronics unit (not shown).

The traction battery 40 also comprises a plurality of cells 41, which are housed in the outer casing 43 and which are connected here in series between the positive 44 and negative 45 terminals.

In a variant the cells could be connected in pairs in parallel, and these pairs of cells could be connected in series between the positive and negative terminals.

The number of cells 41 used is determined such that the electric motor 10 can produce a torque and a power sufficient to propel the motor vehicle 1 for a predetermined period of time.

Since a traction battery cell usually delivers a voltage of approximately 3 to 5 V, the number of cells 41 is calculated such that the voltage at the terminals of the traction battery 40 can reach 400 V.

Each cell 41 of the traction battery 40 will be monitored here independently of the other cells 41. To this end, each cell 41 is characterized here by three specific parameters referred to as the state of charge SOC, maximum capacity Qᵣ, and state of health indicator SOH_E.

The state of charge SOC is expressed as a percentage. It indicates the state of charging of the cell 41 in question, between a minimum state of charge, at which the battery can no longer be used (0%), and a maximum state of charge (100%).

The maximum capacity Qᵣ is expressed in ampere-hours. It indicates the length of time for which the cell 41 can provide an electrical current of a given amperage. At the moment of production of the cell 41, this maximum capacity Qᵣ is generally equal to or slightly less than the nominal capacity Qn for which the cell has been designed. The cell then degrades over the course of time in accordance in particular with the past temperature of the cell 41 and the past charge and discharge cycles thereof.

The state of health indicator SOH_E is expressed as a percentage. It provides information regarding the state of ageing of the cell 41 in question. Generally, at the moment of production of the cell 41, the state of health indicator SOH_E is equal to or slightly less than 100%, then decreases with time, depending on what use is made of the cell 41.

It thus proves to be essential, this also forming the object of the present invention, to precisely determine these three parameters in order to monitor the ageing of the traction battery 40 with a view to preventing failure of the motor vehicle 1.

For this, the motor vehicle 1 comprises a computer 30, which is shown here as being independent of the traction battery 40. In a variant this computer could be integrated in the battery. In accordance with another variant the computer could be an integral part of the overall control unit of the electric motor.

Here, as shown in FIG. 1, the computer 30 comprises a processor (CPU), a random-access memory (RAM), a read-only memory (ROM), analog-digital converters (A/D), and different input and output interfaces.

Thanks to its input interfaces, the computer 30 is able to receive, from different sensors, input signals relating to the traction battery 40.

In its random-access memory, the computer 30 thus memorizes continuously:
the temperature T of the traction battery 40, measured here with the aid of a temperature sensor situated in the outer casing 43 of the traction battery 40,
the amperage I of the current drawn by the traction battery 40, with the aid of a current sensor electrically connected between the cells 41 and the negative terminal 45 of the traction battery 40, and
the voltage V_{cell} at the terminals of each cell 41, with the aid of voltmeters electrically connected to the terminals of the cells 41 of the traction battery 40.

Thanks to a piece of software stored in its read-only memory, the computer 30 is able to determine the state of charge SOC, the maximum capacity Qᵣ and the state of health indicator SOH_E of each cell 41 in accordance with the measured values.

Lastly, thanks to its output interfaces, the computer is able to transmit this data to the overall control unit of the electric motor 10.

Here, the functioning of the software will be described with reference to a single cell 41 of the traction battery 40. In practice, it will be implemented in the same way for each of the other cells of the traction battery 40.

Upon start-up, the computer 30 implements an initialization operation, during which it assigns “initial estimated values” to different parameters, in particular to the state of charge SOC, to the maximum capacity Qᵣ, and to the state of health indicator SOH_E.

These initial values may be selected for example to be equal to the values calculated during the previous operating cycle of the electric motor 10.

Upon the first start-up of the motor, the initial values may be selected for example as follows:
SOC=100%,
Qᵣ=Qₙ, and
SOH_E=100%.

The computer 30 then implements an algorithm in four steps, which are repeated recurrently with each time step (the time step in question being denoted k here).

The first step is a step of acquiring the parameters of the relevant cell 41 of the traction battery 40.

The second step is a step of calculating the maximum capacity Qᵣ and the state of charge SOC of the cell 41.

The third step is a step of validating the calculated data.

The fourth step is a step of calculating the state of health indicator SOH_E of the cell 41 and a state of health indicator SOH_E of the traction battery 40.

During the first step, the computer 30 acquires the values of the voltage V_{cell} at the terminals of the cell 41 in question, the amperage I of the current passing through said cell 41, and the temperature T of the traction battery 40.

The second step, which consists of calculating the maximum capacity Qᵣ and the state of charge SOC of the cell 41, is carried out here by means of a state observer.

A state observer of this type is used in order to reconstruct, on the basis of the measurements, the internal variables of a dynamic system. On the basis of an on-board model of the cell and the value of the input current, the observer predicts the voltage of said cell. It then compares this prediction with the voltage measurement of the cell. The difference between predicted voltage and measured voltage is used to adapt the internal states of the model and converge them so as to cancel out the difference between predicted voltage and measured voltage.

Here, in accordance with a particularly advantageous feature of the invention, the calculation of the maximum capacity Qᵣ and the state of charge SOC of the cell 41 is performed by resolving:
a system of discretized equations corresponding to a modeling of the cell 41 as an electric circuit 42 comprising, in series, an ideal voltage source E_{eq}, a resistor R_{Ω}, a first resistor R_{ct} and capacitor C_{dl} pair connected in parallel, and at least one second resistor Rᵢ and capacitor Cᵢ pair connected in parallel, and
a discretized equation for estimating the variation of the maximum capacity Qᵣ of the cell 41.

In theory, these equations have been formulated in the following way.

As shown in FIG. 2, the cell 41 is modeled in the form of an electric circuit 42 comprising ideal components.

In this model the ideal voltage source E_{eq} models the electrochemical potential of the cell. The difference in potentials at the terminals of this ideal voltage source E_{eq} is thus directly dependent on the state of charge SOC of the cell 41.

The resistor R_{Ω} models the voltage drop induced by the connection of the cell 41 and the internal resistance of the cell 41.

In the first resistor R_{ct} and capacitor C_{dl} pair connected in parallel the resistor R_{ct} models the charge transfer phenomenon and the capacitor C_{dl} represents the double-layer phenomenon at the electrode/electrolyte interfaces. V_{dl} is the voltage at the terminals of this first pair.

Here, N pairs of resistor Rᵢ and capacitor Cᵢ connected in parallel are provided, with i ranging from 1 to N. These N pairs model the phenomenon of lithium ion diffusion in the cell 41 and in the electrodes of the cell 41. Vᵢ is the voltage at the terminals of the i^{th} pair. N may be selected to be equal to 2, for example. The modeling of this equivalent electric circuit 42 leads to the following system of equations:

$$\{ \begin{matrix}\frac{dSOC}{dt} = \frac{I}{{Q}_{n}} \\ \frac{{dV}_{dl}}{dt} = - \frac{{V}_{ctdl}}{{R}_{ct} {C}_{dl}} + \frac{I}{{C}_{dl}} \\ \frac{{dV}_{i}}{dt} = - \frac{{V}_{i}}{{R}_{i} {C}_{i}} + \frac{I}{{C}_{i}}\end{matrix} , \\ for \\ i = 1 … N \\ {V}_{Cell} = {E}_{eq} ( SOC ) + {R}_{Ω} \cdot I + {V}_{ctdl} + {\sum }_{i = 1}^{N} {V}_{i}$$

The equation for estimating the variation of the maximum capacity Qᵣ of the cell 41 is in turn obtained on the basis of the following observation: when the state of charge SOC develops rapidly during a charge or discharge cycle, when the voltage V_{dl} may vary from 0 V to a few tens of volts within a few seconds, and when the diffusion polarization Σᵢ₌₁^{N}Vᵢ may pass from 0 V to a few tens of volts within a few minutes, the maximum capacity Qᵣ of the cell 41 varies very slowly (on average by approximately 20% in 5 years).

As a result, the hypothesis of considering a variation of maximum capacity Qᵣ of zero between two time steps is reasonable. This is written as follows:

$$\frac{d Δ Q}{dt} = 0 , \\ with$$

$$Δ Q = \frac{{Q}_{n}}{{Q}_{r}} - 1.$$

It should be noted here that the use of this parameter ΔQ rather than the maximum capacity Qᵣ will improve the functioning of the algorithm and will avoid numerical problems, which could result in the divergence of said algorithm.

The discretization of these equations makes it possible to obtain the following system:

$$\{ \begin{matrix}SOC ( k ) = SOC ( k - 1 ) + \frac{( 1 + Δ Q ) \cdot I ( k - 1 ) \cdot {T}_{e}}{{Q}_{n}} \\ Δ Q ( k ) = Δ Q ( k - 1 ) \\ {V}_{cl} ( k ) = ( 1 - \frac{{T}_{e}}{{R}_{ct} {C}_{dl}} ) \cdot {V}_{ctdl} ( k - 1 ) + \frac{I ( k - 1 ) \cdot {T}_{e}}{{C}_{dl}} \\ {V}_{i} ( k ) = ( 1 - \frac{{T}_{e}}{{R}_{i} {C}_{i}} ) \cdot {V}_{i} ( k - 1 ) + \frac{I ( k - 1 ) \cdot {T}_{e}}{{C}_{i}}\end{matrix} , \\ where \\ i = 1 … N \\ {V}_{cell} ( k ) = {E}_{eq} ( SOC ( k ) ) + {R}_{Ω} \cdot I ( k ) + {V}_{ctdl} ( k ) + {\sum }_{i = 1}^{N} {V}_{i} ( k )$$

In this system of equations Tₑ is the sampling period.

The state observer used here to obtain, with each time step k, a good evaluation of the maximum capacity Qᵣ and the state of charge SOC of the cell 41 is an extended Kalman filter.

In practice, the computer 30 carries out a plurality of calculations based on this extended Kalman filter in order to obtain estimations of the maximum capacity Qᵣ and the state of charge SOC of the cell 41.

These calculations are known to a person skilled in the art and therefore will not be described here in detail. For further details, reference could be made for example to the work entitled “Optimal State Estimation” by Dan Simon, published in Wiley editions.

To summarize, this state observer uses a state vector xₖ, an input vector uₖ, an output vector yₖ, a state noise ωₖ, and a measurement noise νₖ. The following stochastic system is then considered:

$$\{ \begin{matrix}{x}_{k} = {f}_{k - 1} ( {x}_{k - 1} , {u}_{k - 1} , {ω}_{k - 1} ) \\ {y}_{k} = {h}_{k} ( {x}_{k} , {u}_{k} , {v}_{k} ) \\ {ω}_{k} ( 0 , {Q}_{k} ) \\ {v}_{k} ( 0 , {R}_{k} )\end{matrix}$$

In this system, Rₖ is the measurement noise covariance matrix and Qₖ is the state noise covariance matrix. In practice, the state vector xₖ is defined as follows:

$${x}_{k} = [ \begin{matrix}SOC ( k ) \\ Δ Q ( k ) \\ {V}_{dl} ( k ) \\ {V}_{1} ( k ) \\ ⋮ \\ {V}_{N} ( k )\end{matrix} ]$$

The output vector yₖ is thus defined:

yₖ=V_{cell}(k)

The input vector uₖ is thus defined:

uₖ=l(k)

The functions fₖ₋₁ and hₖ are obtained with the aid of the system of discretized equations mentioned above.

The computer 30 then linearizes the system of equations by calculating the following Jacobian matrices:

$${F}_{k - 1} = \frac{\partial {f}_{k - 1}}{\partial x} {\vert}_{{\hat{x}}_{k - 1}^{+}} \\ {L}_{k - 1} = \frac{\partial {f}_{k - 1}}{\partial ω} {\vert}_{{\hat{x}}_{k - 1}^{+}}$$

It then estimates the estimation error covariance matrix of the state variable Pₖ and the state variable xₖ as follows:

Pₖ⁻=Fₖ₋₁Pₖ₋₁⁺Fₖ₋₁^{T}+Lₖ₋₁Qₖ₋₁Lₖ₋₁^{T}

\hat{x}ₖ⁻=fₖ₋₁(\hat{x}ₖ₋₁⁻,uₖ₋₁,0)

The computer 30 then linearizes these equations by calculating the following Jacobian matrices:

$${H}_{k} = \frac{\partial {h}_{k}}{\partial x} {\vert}_{{\hat{x}}_{k}^{-}} \\ {M}_{k} = \frac{\partial {h}_{k}}{\partial v} {\vert}_{{\hat{x}}_{k}^{-}}$$

Lastly, the computer 30 updates the Kalman gain Kₖ, estimates the state variable xₖ and the estimation error covariance matrix of the state variable Pₖ as follows:

Kₖ=Pₖ⁻Hₖ^{T}(HₖPₖ⁻Hₖ^{T}+MₖRₖMₖ^{T})⁻¹

\hat{x}ₖ⁺=\hat{x}ₖ⁻+K^{k}[y^{k}−h(\hat{x}ₖ⁻,uₖ,0)]

Pₖ⁺=(I−PₖHₖ)Pₖ⁻

The computer 30 thus obtains the values of the maximum capacity Qᵣ and of the state of charge SOC of the cell 41.

The accuracy of the modeling makes it possible to choose a dynamic parameterization of the observer leading to a rapid convergence.

The third step is a step of validating the calculated data.

This step consists of verifying on the one hand if the calculated value of the maximum capacity Qᵣ has sufficiently converged to be usable and on the other hand whether the conditions of use of the cell 41 are close to the conditions of characterization thereof in early life (when the maximum capacity Qᵣ of the cell was considered to be equal to the nominal capacity Qₙ). In other words, comparison data is effectively provided making it possible to determine the irreversible loss of capacity. In order to verify that the algorithm has sufficiently converged, the computer 30 determines the difference between the maximum capacity Qᵣ(k) last calculated and the maximum capacity Qᵣ(k−k′) calculated a few time steps before, then estimates that the maximum capacity Qᵣ has sufficiently converged if this difference is lower than a predetermined threshold S0. Here, the computer 30 considers that the maximum capacity Qᵣ has sufficiently converged if:

|Qᵣ(k)−Qᵣ(k−10)|<S0.

In order to check that the conditions of use of the cell 41 are close to the conditions of characterization in the early life of said cell, the computer 30 uses at least the temperature T(k) acquired during the first step. It preferably also uses the values of voltage V_{cell}(k), of current I(k), and of state of charge SOC(k).

Here, the computer 30 considers that the conditions of use of the cell 41 are close to the conditions of use in the early life of said cell if:

Tmin,charac<T(k)<Tmax,charac,

SOCmin,charac<SOC(k)<SOCmax,charac,

Vmin,charac<V(k)<Vmax,charac,

Imin,charac<I(k)<Imax,charac

with Tmin,charac, Tmax,charac, SOCmin,charac, SOCmax,charac, Vmin,charac, Vmax,charac, Imin,charac and Imax,charac being, respectively, the minimum and maximum characterization temperatures, states of charge, cell voltage, and current.

When the computer 30 considers that the maximum capacity Qᵣ has sufficiently converged and that the conditions of use of the cell 41 are close to the characterization conditions in the early life of said cell, it assigns the value 1 to a validity indicator δ. Otherwise, it assigns the value 0 to this validity indicator δ.

As will become clear from the description hereinafter, the use of this validity indicator δ and of the state of health indicator SOH_E prevents reversible variations of maximum capacity Qᵣ from being considered as being caused by ageing.

The fourth step consists of calculating the state of health indicator SOH_E of the cell 41, then deducing from this the state of health indicator SOH_E of the traction battery 40.

For this, an intermediate ageing indicator SOH_Eᵢₙₜ is calculated with the aid of the following formula:

$${SOH\_E}_{int} ( k ) = δ \frac{{Q}_{r} ( k )}{{Q}_{n}} + ( 1 - δ ) {SOH\_E}_{int} ( k - 1 )$$

This intermediate ageing indicator SOH_Eᵢₙₜ is then filtered by a robustness filter, which limits the sudden variations of said indicator. This filter is, here, a filter said to be a ‘moving average filter’.

Thanks to this robustness filter, the computer 30 obtains the state of health indicator SOH_E of the cell 41.

FIG. 3 shows the convergences of the estimation of the maximum capacity Qᵣ, of the intermediate ageing indicator SOH_Eᵢₙₜ, and of the state of health indicator SOH_E.

It can be seen in this figure that in a first period (part A) the maximum capacity Qᵣ has not yet converged, although the validity indicator δ is held equal to 0. As a result, the ageing indicators SOH_Eᵢₙₜ and SOH_E do not vary.

In a second period (part B), the computer 30 estimates that the maximum capacity Qᵣ has converged and therefore assigns the value 1 to the validity indicator δ. The intermediate ageing indicator SOH_Eᵢₙₜ then varies suddenly so as to converge toward the value of the ratio Qᵣ/Qₙ. Thanks to the filter, the state of health indicator SOH_E varies less suddenly for its part, so as to converge progressively toward the value of this ratio (part C).

Lastly, the computer 30 determines the state of health indicator SOH_E of the traction battery 40.

For this, the computer 30 assigns to the state of health indicator SOH_E of the traction battery 40 the value of the state of health indicator SOH_E of the cell 41 which is the oldest, in accordance with the following formula:

SOH_E_{battery}=min(SOH_E_{cells})

At this stage, the computer 30 can also reliably determine if one of the cells 41 is defective.

For this, it compares the values of the ageing indicators SOH_E of each cell with a reached value. This reached value may be formed for example by the average of the ageing indicators SOH_E of the cells 41. The computer 30 deduces a malfunction from this if this difference exceeds a predetermined value, for example equal to 30%.

The present invention is in no way limited to the described and shown embodiment, and a person skilled in the art will be able to provide variants without departing from the scope of the invention.

Thus, for example, the temperature could be measured with the aid of a sensor placed against the outer face of the outer casing of the traction battery. A plurality of temperature sensors could also be used in order to obtain a better estimation of the temperature at the cell in question.

In accordance with another variant, the state of health indicator of the cell could be considered to be constituted by the maximum capacity of said cell.

In yet a further variant, a parameter different from ΔQ could be used to calculate the state of charge SOC and the maximum capacity Qᵣ. Thus, a parameter R equal to the ratio of the nominal capacity Qₙ to the maximum capacity Qᵣ of the cell could be considered, for example.

The discretized equation for estimating the variation of the maximum capacity Qᵣ of the cell 41 would then be expressed in the following form:

β(k)=β(k−1), with β(k)=Qₙ/Qᵣ(k).

In accordance with another variant, the parameter ΔQ could be used, remembering however that this parameter varies slightly between two time steps, for example in accordance with one or other of the parameters constituted by the state of charge SOC, the amperage I, and the temperature T of the cell 41 in question.

In this variant the discretized equation for estimating the variation of the maximum capacity of the cell would then be expressed in the following form:

ΔQ(k)=g(SOC(k−1),ΔQ(k−1),I(k−1),T(k−1)),

where g is a function representative of the dynamic of variation of the capacity of the cell.

1-13. (canceled)

14. A method for estimating the ageing of at least one cell of a storage battery, said method comprising:
a) acquiring a voltage at terminals of said cell and an amperage of current passing through said cell, and
b) calculating a maximum capacity and a state of charge of said cell in accordance with the voltage and the amperage acquired in step a),
wherein the calculating is performed by resolving:
a system of discretized equations corresponding to a modeling of said cell as an electric circuit comprising, in series, an ideal voltage source, a resistor, a first resistor and capacitor pair connected in parallel, and at least one second resistor and capacitor pair connected in parallel, and
a discretized equation for estimating the variation of the maximum capacity of said cell.

15. The estimation method as claimed in claim 14, wherein said system of discretized equations is expressed in the following form:
$$\{ \begin{matrix}SOC ( k ) = SOC ( k - 1 ) + \frac{( 1 + Δ Q ) \cdot I ( k - 1 ) \cdot {T}_{e}}{{Q}_{n}} \\ {V}_{dl} ( k ) = ( 1 - \frac{{T}_{e}}{{R}_{ct} {C}_{dl}} ) \cdot {V}_{dl} ( k - 1 ) + \frac{I ( k - 1 ) \cdot {T}_{e}}{{C}_{dl}} \\ {V}_{i} ( k ) = ( 1 - \frac{{T}_{e}}{{R}_{i} {C}_{i}} ) \cdot {V}_{i} ( k - 1 ) + \frac{I ( k - 1 ) \cdot {T}_{e}}{{C}_{i}}\end{matrix} , \\ {V}_{cell} ( k ) = {E}_{eq} ( k ) + {R}_{Ω} \cdot I ( k ) + {V}_{dl} ( k ) + {\sum }_{i = 1}^{N} {V}_{i} ( k )$$
with:
Tₑ a considered sampling period,
k an incremental index,
SOC the state of charge of said cell,
I the amperage of the current passing through said cell,
ΔQ a function of a nominal capacity in the early life of the cell and the instantaneous maximum capacity of the cell,
V_{cell} the voltage at the terminals of the electric circuit,
V_{dl} the voltage at the terminals of the first resistor and capacitor pair, of which the values are denoted R_{ct} and C_{dl} respectively, and
Vᵢ the voltage at the terminals of the second resistor and capacitor pair, of which the values are denoted Rᵢ and Cᵢ respectively.

16. The estimation method as claimed in claim 14, wherein said discretized equation for estimating the variation of the maximum capacity of said cell is expressed in accordance with a parameter relating to a nominal capacity in the early life of said cell and to the instantaneous maximum capacity of said cell.

17. The estimation method as claimed in claim 16, wherein said discretized equation for estimating the variation of the maximum capacity of said cell is expressed in the following form:
ΔQ(k)=ΔQ(k−1), k being an incremental index.

18. The estimation method as claimed in claim 16, wherein said discretized equation for estimating the variation of the maximum capacity of said cell is expressed in the following form:
ΔQ(k)=g(SOC(k−1),ΔQ(k−1),I(k−1),T(k−1)), where:
k is an incremental index,
g is a function representative of the dynamic of variation of the capacity of the cell,
SOC is the state of charge of said cell,
I is the amperage of the current passing through said cell, and
T is a temperature measured across said cell.

19. The estimation method as claimed in claim 14, wherein the calculating includes resolving said equations with the aid of a state observer of which the state vector comprises:
the state of charge of said cell,
the maximum capacity of said cell,
the voltage at the terminals of the first resistor and capacitor pair, and
the voltage at the terminals of each pair i of resistor and capacitor.

20. The estimation method as claimed in claim 14, wherein the calculating includes resolving said equations with the aid of a state observer of which the output vector comprises the voltage at the terminals of the electric circuit.

21. The estimation method as claimed in claim 14, further comprising:
c) calculating a state of health indicator of said cell in accordance with the maximum capacity of said cell calculated in step b).

22. The estimation method as claimed in claim 21, wherein in step c) the value of said state of health indicator is modified only if the variation of the maximum capacity of said cell is lower than a predetermined threshold.

23. The estimation method as claimed in claim 21, wherein in step c) the value of said state of health indicator is modified only if the measured temperature of said storage battery is within a characterization temperature range in the early life of said storage battery.

24. The estimation method as claimed in claim 21, wherein in step c) the value of said state of health indicator is modified only if the state of charge of said storage battery is within a characterization range in the early life of said storage battery.

25. The estimation method as claimed in claim 21, wherein in step c) the value of said state of health indicator is modified only if the voltage acquired in step a) is within a characterization voltage range in the early life of said storage battery.

26. The estimation method as claimed in claim 21, wherein in step c) the value of said state of health indicator is modified only if the amperage acquired in step a) is within a characterization amperage range in the early life of said storage battery.
